(19) United States
(12) Patent Application Publication
(10) Pub. No.: US 2006/0166513 A1
(43) Pub. Date: Jul. 27, 2006

(54) Method and apparatus for forming thin film of semiconductor device

(76) Inventor: Jun-Seuck Kim, Seoul (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/328,097

(22) Filed: Jan. 10, 2006

(30) Foreign Application Priority Data
Jan. 21, 2005 (KR) 2005-0005636

(51) Int. Cl. H01L 21/31

(52) U.S. Cl. 438/787; 438/770

(57) ABSTRACT

A method of forming a high quality thin film on a semiconductor substrate includes supplying a first gas to change a crystal structure of a semiconductor substrate, and a second gas to form a thin film on the semiconductor substrate; sputtering the first gas in a plasma state to the semiconductor substrate to detach some of the atoms of the semiconductor substrate and concurrently, change a crystal structure of a surface of the semiconductor substrate; and forming a thin film on the semiconductor substrate by reacting the second gas as a reactant gas with the detached atoms and the atoms of the surface of the semiconductor substrate. An apparatus is also provided for performing this process.

### CROSS-REFERENCE TO RELATED APPLICATION

This application claims the benefit of Korean Patent Application No. 10-2005-0005636, filed Jan. 21, 2005, the disclosure of which is hereby incorporated herein by reference in its entirety for all purposes as if fully set forth herein.

### BACKGROUND OF THE INVENTION

1. Technical Field

The present invention relates to a method and an apparatus for fabricating a semiconductor device, and more particularly, to a method and an apparatus for forming a thin film on a semiconductor substrate.

2. Discussion of Related Art

Recently, development of semiconductor devices has been made toward a high integration and a high performance in order to process more data in a short time. A thin film deposition technique for forming a thin film pattern precisely on a semiconductor substrate is very important in order to realize a semiconductor device having a high integration and a high performance.

Normally, the technique for forming a thin film on a wafer include the physical vapor deposition (PVD) technique and the chemical vapor deposition (CVD) technique.

A process using the PVD technique is performed by vaporizing the same material as that of a desired thin film to deposit the vaporized material on a substrate. The PVD technique is classified into a vacuum evaporation process and a sputtering process, and is a technique for depositing a desired thin film on a substrate using a method in which a chemical reaction is not involved.

In the vacuum evaporation process, a desired deposition source is thermally evaporated or sublimed in a vacuum to be changed into deposition particles, and then, the deposition particles are moved to a substrate and deposited or stacked on the substrate, thereby forming a thin film.

In contrast, the sputtering process uses a sputtering phenomenon, in which component atoms are emitted from the surface of a target when high energy particles are shot to a solid material (target). That is, if particles having hundreds of eV through dozens of keV of energy are applied to the target, target atoms having a movement toward a direction opposite to the target surface come out from the target by a cascade phenomenon caused by nucleus collision of the applied ions and the target atoms. The target atoms emitted by the sputtering phenomenon are moved to a substrate, thereby forming a thin film.

The CVD technique is a method of supplying one kind of gas, compounds, or plural gases composed of atoms, to form a desired thin film on a substrate, and forming the desired thin film by a chemical reaction, such as thermal decomposition, optical decomposition, oxidation-reduction, reduction, and the like on the substrate or the surface of the substrate. The CVD technique is classified into a thermal CVD process, plasma enhanced CVD (PECVD) process, and the like.

In the thermal CVD process, source gas is thermally decomposed on the surface of a substrate heated at a predetermined temperature by heat energy, and a thin film is formed by the decomposed material or chemical reaction. The thermal CVD technique includes atmospheric pressure CVD (APCVD) at atmospheric pressure, and low pressure CVD (LPCVD) at a reduced pressure of several torr.

The PECVD process forms a thin film by active particles, which are generated in source gas plasma and activate a chemical reaction on the surface of a substrate.

The CVD technique is used to deposit various thin films such as a silicon oxide layer, a silicon nitride layer, and the like on a wafer.

FIGS. 1 and 2 illustrate an oxide layer deposition process and a crystal structure of a semiconductor substrate using an LPCVD process as a deposition technique typically used for deposition of an oxide layer, and the like.

As shown in FIG. 1, the semiconductor substrate having a silicon crystal structure is prepared inside a chamber, and oxygen ions (O+) are supplied. The oxygen ions (O+) are diffused into the semiconductor substrate as shown in FIG. 2, and bonded with the silicon (Si) of the semiconductor substrate, thereby forming an oxide layer. Since the oxide layer is formed by a high temperature, impurity gases cause a chemical reaction in the high temperature state so as to contaminate the surface of the silicon wafer. This deteriorates the quality of the deposited thin film. That is, other ions (for example, boron ions) are coupled to dangling bonds of the silicon, which are not bonded with the oxygen ions (O+). As a result, mobile charges are generated, which prevents with a performance improvement of the semiconductor device.

### SUMMARY OF THE INVENTION

Therefore, the present invention is directed to provide a method and an apparatus for forming a thin film on a semiconductor substrate to fabricate a semiconductor device being capable of overcoming the conventional problem.

Exemplary embodiments of the present invention provide a method of forming a thin film to fabricate a semiconductor device including supplying a first gas to change a crystal structure of a semiconductor substrate, and a second gas to form a thin film on the semiconductor substrate; sputtering the first gas in a plasma state to the semiconductor substrate to detach some of the atoms of the semiconductor substrate and concurrently, change a crystal structure of a surface of the semiconductor substrate; and forming a thin film on the semiconductor substrate by reacting the second gas as a reactant gas with the detached atoms and the atoms of the surface of the semiconductor substrate.

In accordance with an exemplary embodiment, the first gas may include argon (Ar) ions, and the thin film may be an oxide layer. Further, the second gas may include oxygen ions, and the semiconductor substrate may be composed of silicon (Si).

In another aspect of the present invention, the present invention provides an apparatus of forming a thin film to fabricate a semiconductor device including a process chamber part in which a thin film is formed on a substrate; a gas injection port installed at one end of the process chamber part and supplying a first gas and a second gas therethrough; a plasma generating part having an RF coil to maintain the supplied first and second gases in a state of high density plasma; a heating part applying heat to the inside of the process chamber; a semiconductor substrate on which a thin film is formed; and a magnetic field generating part disposed below the semiconductor substrate, and generating a magnetic field of sputtering the first gas in a plasma state to the semiconductor substrate.

In accordance with an exemplary embodiment, the first gas may include argon (Ar) ions, and the thin film may be an oxide layer. Further, the second gas may include oxygen ions, and the semiconductor substrate may be composed of silicon (Si).

Therefore, according to the present invention, a high quality of an oxide layer is provided, and a performance of a semiconductor device can be expected.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIGS. 1 and 2 are views illustrating a conventional process of forming an oxide layer and a crystal structure of a semiconductor substrate; and

FIGS. 3 to 5 are views illustrating one embodiment of an improved process of forming an oxide layer and the crystal structure of a semiconductor substrate;

FIG. 6 shows an exemplary apparatus for forming a thin film to fabricate a semiconductor device.

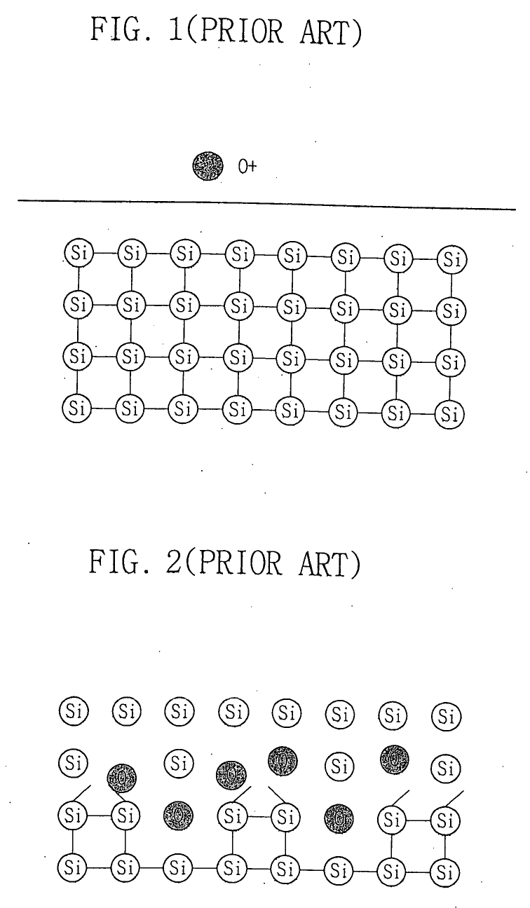

### DETAILED DESCRIPTION

The present invention will now be described with reference to the accompanying drawings, in which preferred embodiments of the invention are shown. However, the invention should not be construed as limited to only the embodiments set forth herein. Rather, these embodiments are presented as teaching examples. In the drawings, like numbers refer to like elements.

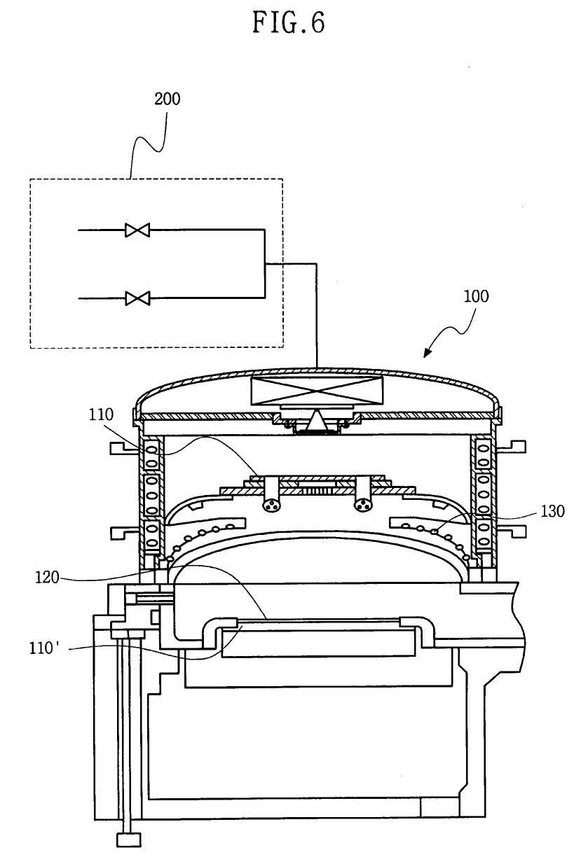

FIG. 6 shows an exemplary apparatus for forming the thin film to fabricate a semiconductor device. The apparatus of FIG. 6 includes: a process chamber part 100 for forming a thin film on a semiconductor substrate; a gas supplying part 200 installed at one end of the process chamber part 100 adapted to supply a first gas and a second gas; a plasma generating part 110 and 110′ having an RF coil for maintaining the supplied first and second gases in a high density plasma state; a heating part 120 for applying heat to the inside of the process chamber part 100; and a magnetic field generating part 130 disposed below the semiconductor substrate and generating a magnetic field such that atoms of the semiconductor substrate are sputtered by the first gas in a plasma state.

The apparatus for forming a thin film to fabricate a semiconductor device is structured to further install the magnetic generating part into a typical chemical vapor deposition apparatus for a sputtering effect, and the structure of the thin film formation apparatus will be well understood to those skilled in this field. The sputtering of the first gas (e.g., Argon) is a distinguishing characteristic of this apparatus and the process described below.

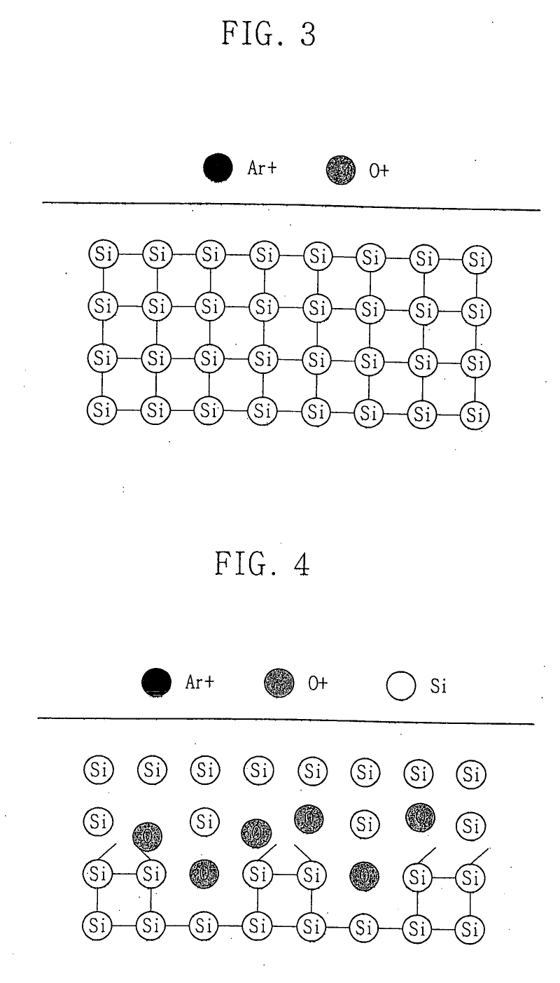

FIGS. 3 to 5 are views illustrating an example of an improved process for forming a thin film silicon oxide (SiO₂) layer on a semiconductor substrate.

As shown in FIG. 3, a semiconductor substrate of silicon (Si) is loaded into the chamber of the thin film formation apparatus. Then, an argon ion (Ar+) gas as a first gas is supplied into the chamber so as to generate plasma of the argon ion (Ar+) gas on the semiconductor substrate. Then, the argon ion (Ar+) gas plasma is sputtered to the semiconductor substrate. By the sputtering of the argon ion (Ar+) gas, bonding of the silicons (Si) of the semiconductor substrate is broken as shown in FIG. 4, and some of the silicon atoms (Si) are detached from the semiconductor substrate, and the bonding ability of the silicons forming the crystal structure of the semiconductor substrate is deteriorated.

The sputtering of the argon ions (Ar+) is possible by the magnetic field generated by a magnetic field generator installed below a stage on which the semiconductor substrate is placed.

Further, gas including oxygen ions (O+) as a second gas is supplied into the chamber of the thin film formation apparatus through a gas injection port.

FIG. 4 is a view illustrating an intermediate state in which oxygen ion gas and silicon atoms react together. As shown in FIG. 4, the second gas including the oxygen ions (O+) in the plasma state as a reactant gas, the silicon (Si) detached from the semiconductor substrate, and silicon atoms on the surface of the semiconductor substrate react, thereby forming a thin film on the semiconductor substrate. The oxygen ions (O+) are deposited and are bonded with the silicons (Si), rather than the oxygen ions (O+) being diffused and bonded with the silicons (Si), to form the thin film.

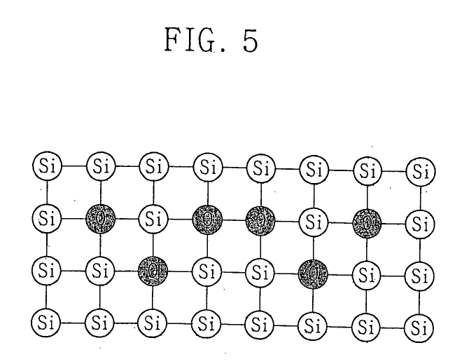

FIG. 5 is a view illustrating the crystal structure of the semiconductor substrate having the thin film formed thereon as described above.

As shown in FIG. 5, dangling bonding of the silicon atoms (Si) of the semiconductor substrate is reduced due to the sputtering effect, thereby providing a high quality oxide layer as compared to that of a typical oxide layer formed using methods described in the background section of this specification. Further, since an embodiment of the method described above can also be performed at a room temperature, generation of problems which may occur due to a high temperature can be prevented or minimized.

As described above, by the sputtering effect described herein, the crystal structure of the semiconductor substrate is changed, thereby providing a high quality oxide layer. Problems due to a high temperature are prevented from being generated, or minimized as compared to the typical thin film formation method that uses a high temperature, thereby improving a performance of a semiconductor device.

The invention has been described using preferred exemplary embodiments. However, it is to be understood that the scope of the invention is not limited to the disclosed embodiments. On the contrary, the scope of the invention is intended to include various modifications and alternative arrangements within the capabilities of persons skilled in the art using presently known or future technologies and equivalents. The scope of the claims, therefore, should be accorded the broadest interpretation so as to encompass all such modifications and similar arrangements.

What is claimed is:

1. A method of forming a thin film to fabricate a semiconductor device comprising:
supplying a first gas to change a crystal structure of a semiconductor substrate, and a second gas to form a thin film on the semiconductor substrate;
sputtering the first gas in a plasma state to the semiconductor substrate to detach some of the atoms of the semiconductor substrate and concurrently, change a crystal structure of a surface of the semiconductor substrate; and
forming a thin film on the semiconductor substrate by reacting the second gas as a reactant gas with the detached atoms and the atoms of the surface of the semiconductor substrate.

2. The method according to claim 1, wherein the first gas includes argon (Ar) ions.

3. The method according to claim 2, wherein the thin film is an oxide layer.

4. The method according to claim 3, wherein the second gas includes oxygen ions.

5. The method according to claim 4, wherein the semiconductor substrate comprises silicon (Si).

6. An apparatus of forming a thin film to fabricate a semiconductor device comprising:
a process chamber part adapted to form a thin film on a semiconductor substrate;
a gas injection port installed at one end of the process chamber part adapted to supply a first gas and a second gas therethrough;
a plasma generating part having an RF coil adapted to maintain the supplied first and second gases in a state of high density plasma;
a heating part adapted to apply heat to an inside of the process chamber; and
a magnetic field generating part disposed below the semiconductor substrate, and generating a magnetic field adapted to sputter the first gas in a plasma state to the semiconductor substrate.

7. The apparatus according to claim 6, wherein the first gas includes argon (Ar) ions.

8. The apparatus according to claim 7, wherein the thin film is an oxide layer.

9. The apparatus according to claim 8, wherein the second gas includes oxygen ions.
